(19) United States
(12) Patent Application Publication
(10) Pub. No.: US 2008/0129306 A1
(43) Pub. Date: Jun. 5, 2008

(54) Multi-Point, Multi-Parameter Data Acquisition For Multi-Layer Ceramic Capacitor Testing

(75) Inventors: Kenneth V. Almonte, Portland, OR (US); Charles Bickford, St. Heleus, OR (US)

Correspondence Address: YOUNG & BASILE, P.C., 3001 WEST BIG BEAVER ROAD, SUITE 624, TROY, MI, 48084, US

(73) Assignee: ELECTRO SCIENTIFIC INDUSTRIES, INC., Portland, OR (US)

(21) Appl. No.: 11/565,459

(22) Filed: Nov. 30, 2006

(51) Int. Cl. G01R 31/12

(52) U.S. Cl. 324/519

(57) ABSTRACT

A method for testing at least one multi-layer ceramic capacitor part includes charging, holding, and/or discharging at least one part with respect to a programmed voltage over a predetermined period of time, periodically measuring at least one value corresponding to quality of each part to be tested while each part is being charged, held, and discharged. The at least one value can be selected from a group consisting of voltage value, current value, leakage current value, capacitance value, dissipation factor value, and any combination thereof. Curves can be digitized from the periodically measured values collected while each part is being charged, held, and discharged with respect to the programmed voltage.

### FIELD OF THE INVENTION

The present invention relates to data acquisition during multi-layer ceramic capacitor testing, and in particular to multi-point, multi-parameter data acquisition during multi-layer ceramic capacitor testing.

### BACKGROUND

A manufacturer of multi-layer ceramic capacitors uses a test system to determine the quality of a lot of product before the product is sold to a customer. The test system performs several tests which provide data on the capacitance, dissipation factor, and insulation resistance. The data can then be used to sort the parts by tolerance and find those parts that are defective.

Tests are performed in sequence. The sequence will vary depending on individual manufacturer requirements. For example, the following sequence can be used. Referring to FIGS. 1 and 2, a part can first undergo a capacitance and dissipation factor measurement at one station using a capacitance meter. Referring to FIG. 1 a theoretical plot of voltage across a capacitor being tested versus time is illustrated, where at t₀ the part is at zero volts. At t₁, the part begins charging. At t₂, the part has reached a programmed value. At t₃, all measurements are complete and the part can begin discharging. At t₄, the part is discharged to zero volts. Referring now to FIG. 2 a theoretical plot of current through the capacitor being tested versus time is illustrated, where at t₀ the part is at zero volts, and therefore has no current flowing through the part. At t₁, the part begins charging. The part is charged with a constant-current source. At t₂, the part is charged so it no longer accepts current. This graph assumes an ideal capacitor and neglects parasitics, such as leakage current and dielectric absorption. At t₃, the part begins discharging, so current flows in the reverse direction until the part reaches zero volts at t₄. The part can then move to another station, where the part can be charged to a programmed voltage by a programmable voltage and current source. The part can then be held at the programmed voltage for a certain period of time, called the “soak time”. After this period of time, an insulation resistance measurement can be performed by a high resistance meter. This measurement returns a single value in units of either current or resistance. The current measured is the leakage current through the capacitor when a voltage V is applied, and the resistance R is calculated from V divided by leakage current, where V is an input parameter. Referring now to FIG. 3, a theoretical plot of leakage current through the capacitor being tested versus time is illustrated. At t₀, the part is at zero volts, so there cannot be any current flow. At t₁, the part begins charging. Leakage current values are typically in the picoamps to microamp range, so this measurement must be very sensitive. Therefore, during the charge period, the current (milliamps) is greater than the measurement range, so the output reaches a maximum value. At t₂ voltage continues to be applied to the capacitor under test. The leakage current will begin to decrease because the dielectric is becoming more and more polarized. This is due in part to an effect known as dielectric absorption, and the magnitude of the effect will vary with different dielectrics. If the time axis were extended to several minutes or hours, this curve would continue to decrease exponentially until it reached a nominal value. At some point between t₂ and t₃, the insulation resistance or leakage current measurement is performed. This takes a snapshot of the leakage current at that time. Once that test is completed at t₃, the part is discharged. Again, the high discharge current will cause the perceived leakage to be at a maximum in the other direction. At t₄, the part returns to zero volts. Once this measurement is complete, the part can be discharged and prepared for sorting based on the values collected or prepared for a repeat test.

As ceramic capacitors become smaller and higher in capacitance, the effects of the dielectric and parasitic elements become more pronounced and more complex. Ideally, the electrical properties of a capacitor would be observed for a long period of time to minimize the effect of parasitics. However, this is not feasible from a manufacturing stand point because it would take too long to test millions of devices. Therefore, the industry relies on only a short snapshot of this time to make a determination of the status of the parts. Insuring the accuracy and reliability of the data is crucial, as it directly affects the customers' yield and the quality of the delivered product.

The industry standard for measuring the leakage current through a capacitor is to use an Agilent 4349B High Resistance Meter in combination with a programmable voltage and current source. The Agilent 4349B is a high precision instrument which uses an integrating current-to-voltage converter and a selectable integration time of 10, 30, 100 and 400 milliseconds. Using a longer integration time provides a higher signal-to-noise ratio, which is useful when measuring extremely small currents. The output of the meter is a single current reading after this integration period is complete. Therefore, the user relies on one measurement to decide whether a given capacitor is acceptable or not. The user can repeat this test at another station for more data, though doing so increases machine cost and complexity. The user typically wants the measurement to be as accurate as possible, and would like to use the longest integration time possible to maximize the signal-to-noise ratio. However, the user has to consider how much time the user can afford to make this measurement versus the accuracy of the measurement. The voltage and current supply can be any programmable computer-controlled device, such as an Electro Scientific Industries 54XX power supply. This device is synchronized with the Agilent measurement device, as the timing between startup charge and the start of measurement must be very well controlled.

### SUMMARY

A method for testing at least one multi-layer ceramic capacitor part can include charging the at least one part to a programmed voltage for a predetermined period of time, and periodically measuring the voltage and current values of the at least one part while the at least one part is being charged. A method for testing at least one multi-layer ceramic capacitor part can include discharging at least one part from a programmed voltage over a predetermined period of time, and periodically measuring the voltage and current values of the at least one part while the at least one part is being discharged. A method for testing at least one multi-layer ceramic capacitor part can include holding a programmed voltage on the at least one part for a predetermined period of time, and periodically measuring voltage and leakage current values of the at least one part while the programmed voltage is being held on the at least one part.

Other applications of the present invention will become apparent to those skilled in the art when the following description of the best mode contemplated for practicing the invention is read in conjunction with the accompanying drawings.

### BRIEF DESCRIPTION OF THE DRAWINGS

The description herein makes reference to the accompanying drawings wherein like reference numerals refer to like parts throughout the several views, and wherein:

FIG. 1 is a theoretical plot of voltage across a capacitor being tested versus time;

FIG. 2 is a theoretical plot of current through the capacitor being tested versus time;

FIG. 3 is a theoretical plot of leakage current illustrating a single sample point of testing for leakage current through the capacitor being tested versus time;

FIG. 4 is a plot of voltage across a capacitor being tested versus time with multiple sample points used to digitize a wave form according to an embodiment of the invention;

FIG. 5 is a plot of current through the capacitor being tested versus time with multiple sample points used to digitize a wave form according to an embodiment of the invention; and

FIG. 6 is a plot of leakage current through the capacitor being tested versus time with multiple sample points used to digitize a wave form according to an embodiment of the invention.

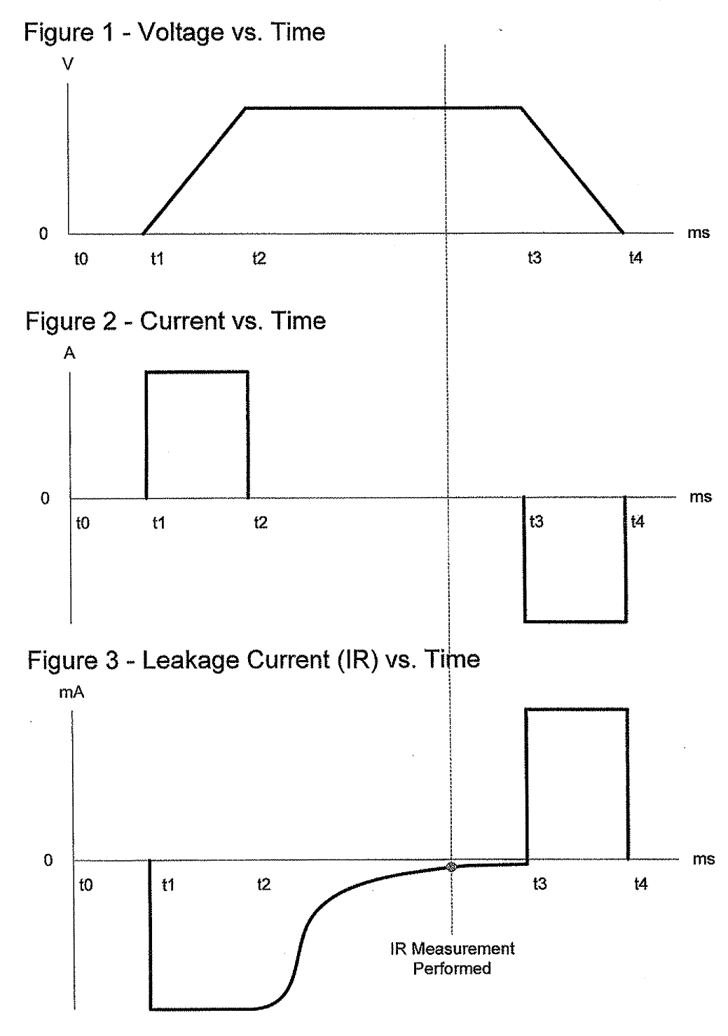

### DETAILED DESCRIPTION

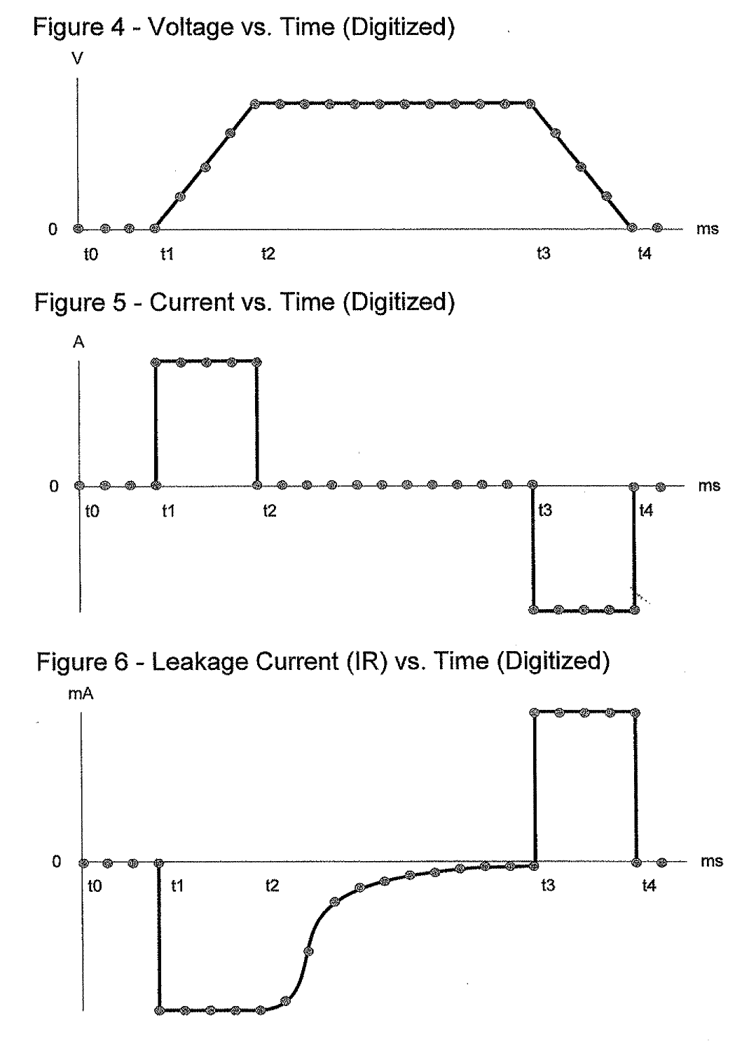

Referring now to FIGS. 4-6, the industry relies on data collected during a short period of time to determine whether a part is satisfactory or defective. The present invention seeks to maximize the information that can be gathered during this time to make a more educated and accurate determination. The term “insulation resistance measurement” is more appropriately described as a measurement of leakage current, since the insulation resistance is equal to the applied voltage divided by leakage current. Rather than taking one voltage, current, and/or leakage current value reading at a certain point in time after the capacitor is charged, these measurements can be taken multiple times, periodically, during charging, holding and discharging the part. This allows the complete digitization of the voltage, current and leakage current curves as illustrated in FIGS. 4-6.

The curves can be fully digitized as shown in FIG. 4 for voltage versus time, in FIG. 5 for current versus time, and in FIG. 6 for leakage current versus time. A part can undergo a capacitance and dissipation factor measurement at one station using a capacitance meter. Referring to FIG. 4, a plot of voltage across a capacitor being tested versus time with multiple sample points being used to digitize a wave form is illustrated according to an embodiment of the invention, where at t₀ the part is at zero volts. At t₁, the part begins charging. At t₂, the part has reached a programmed value. At t₃, charging is complete and the part can begin discharging. At t₄, the part is discharged to zero volts. During each phase of the test i.e. charging, holding programmed value and discharging, periodic measurements are taken to digitize the curve of voltage versus time.

Referring now to FIG. 5, a plot of current through the capacitor being tested versus time with multiple sample points is illustrated to digitize a wave form according to an embodiment of the invention, where at t₀ the part is at zero volts, and therefore has no current flowing through the part. At t₁, the part begins charging. The part is charged with a constant-current source. At t₂, the part is charged so it no longer accepts current. This graph assumes an ideal capacitor and neglects parasitics, such as leakage current and dielectric absorption. At t₃, the part begins discharging, so current flows in the reverse direction until the part reaches zero volts at t₄. During each phase of the test, i.e. charging, holding programmed value and discharging, periodic measurements are taken to digitize the curve of current versus time. This data can be combined with the digitized curve of voltage wave form versus time, and/or the digitized curve of leakage current wave form and saved to a file for further processing. The data can be used by engineers to better understand the capacitors, the process, and the failure modes. The data can also be used to optimize the test, which could then lead to an increase in throughput and even a reduction in machine cost if tests can be shortened or perhaps skipped entirely.

To increase the accuracy of any of the digitized wave forms, i.e. voltage versus time (FIG. 4), current versus time (FIG. 5), and/or leakage current versus time (FIG. 6), over-sampling, averaging, and digital filtering can be employed in the hardware and/or software. Over-sampling is useful in reducing the effects of white noise in the measurement. Essentially each data point would then be the average of the number of samples rather than one input value. Digital filtering can be used to remove unwanted frequencies that could interfere with the data. A major advantage over the existing method is that multiple insulation resistance data points can be analyzed instead of a single insulation resistance data reading that the Agilent 4349B meter provides. Because the industry uses a “predictive” approach to testing capacitors in order to save time and increase throughput, making a determination by analyzing a line is better than analyzing a single point.

The invention can also allow the acquisition of two other parameters, capacitor voltage and capacitor current. The capacitor current is different from leakage current as it is intended to measure the charge and discharge currents, which are much larger (milliamps). These parameters are currently not used in the industry, because the capability is not provided on the equipment used. Therefore, it is not known exactly what information can be extracted from the voltage and current curves. However, being able to acquire the data and process it will be very useful as a research tool to help identify the information present in the curves. Combining these parameters with the leakage current measurement will provide the user with more information for validating the capacitors being tested, the process, and also help to determine the failure modes.

Referring now to FIG. 6, a plot of leakage current through the capacitor being tested versus time with multiple sample points used to digitize a wave form according to an embodiment of the invention is illustrated. At t₀, the part is at zero volts, so there cannot be any current flow. At t₁, the part begins charging. Leakage current values are typically in the picoamps to microamp range, so this measurement must be very sensitive. Therefore, during the charge period, the current (milliamps) is greater than the measurement range, so the output reaches a maximum value. At t₂, voltage continues to be applied to the capacitor under test. The leakage current will begin to decrease because the dielectric is becoming more and more polarized. This is due in part to an effect known as dielectric absorption, and the magnitude of the effect will vary with different dielectrics. If the time axis were extended to several minutes or hours, this curve would continue to decrease exponentially until it reached a nominal value. At periodic points in time between t₀ and t₄, the insulation resistance or leakage current measurement is performed. This takes a plot of the wave form corresponding to leakage current during that time period. Once that test is completed at t₄, the part is discharged. Again, the high discharge current will cause the perceived leakage to be at a maximum in the other direction. At t₄, the part returns to zero volts. The entire wave form may not be digitized, but it is possible to do so. Instead, a portion of the wave form where the leakage current is of interest can be digitized to create a curve rather than a single point. Having several points allows a user to create a trend line and to be able to look for patterns in the data.

While the invention has been described in connection with what is presently considered to be the most practical and preferred embodiment, it is to be understood that the invention is not to be limited to the disclosed embodiments but on the contrary, is intended to cover various modifications and equivalent arrangements included within the spirit and scope of the appended claims, which scope is to be accorded the broadest interpretation so as to encompass all such modifications and equivalent structures as is permitted under the law.

What is claimed is:

1. In a method for testing at least one capacitor part including measuring at least one voltage value and at least one current value, the improvement comprising:
performing at least a portion of a charging, holding, and discharging test cycle on at least one part with respect to at least one of a programmable voltage and a programmable current over a predetermined period of time;
periodically measuring at least one value corresponding to quality of each part to be tested while each part is being subjected to at least a portion of the test cycle of being charged, held, and discharged, the at least one value selected from a group consisting of a voltage value, a current value, a leakage current value, a capacitance value, a dissipation factor value, and any combination thereof; and
digitizing at least one curve from the periodically measured values collected while each part is being subjected to at least a portion of the test cycle of being charged, held, and discharged.

2. The improvement of claim 1, wherein periodically measuring at least one value further comprises:
periodically measuring a leakage current value of the at least one part while the at least one part is being subjected to at least a portion of the test cycle of being charged, held, and discharged.

3. The improvement of claim 2, wherein digitizing at least one curve further comprises:
digitizing a leakage current curve versus time from the periodically measured leakage current values collected while each part is being subjected to at least a portion of the test cycle of being charged, held, and discharged.

4. The improvement of claim 1, wherein periodically measuring at least one value further comprises:
periodically measuring a voltage value of the at least one part while the at least one part is being subject to at least a portion of the test cycle of being charged, held, and discharged.

5. The improvement of claim 4, wherein digitizing at least one curve further comprises:
digitizing a voltage curve versus time from the periodically measured voltage values collected while each part is being subjected to at least a portion of the test cycle of being charged, held, and discharged.

6. The improvement of claim 1, wherein periodically measuring at least one value further comprises:
periodically measuring a current value of the at least one part while the at least one part is being subject to at least a portion of the test cycle of being charged, held, and discharged.

7. The improvement of claim 6, wherein digitizing at least one curve further comprises:
digitizing a current curve versus time from the periodically measured current values collected while each part is being subjected to at least a portion of the test cycle of being charged, held, and discharged.

8. The improvement of claim 1 further comprising:
over-sampling the periodically measured leakage current values to reduce effects of white noise during measurements.

9. The improvement of claim 1 further comprising:
averaging groups of the periodically measured leakage current values into averaged periodically measured leakage current values.

10. The improvement of claim 1 further comprising:
digitally filtering the periodically measured leakage current values to remove unwanted frequencies that could interfere with collected data.

11. The improvement of claim 1 further comprising:
periodically measuring capacitance values and dissipation factor values of the at least one part while the at least one part is being subject to at least a portion of a test cycle of being charged, held, and discharged.

12. A method for testing at least one multilayer ceramic capacitor part comprising:
holding at least one part at a programmed voltage over a predetermined period of time; and
periodically measuring leakage current of the at least one part while the at least one part is being held at the programmed voltage.

13. The method of claim 12 further comprising:
digitizing a curve from the periodically measured leakage current values while the at least one part is being held at the programmed voltage.

14. The method of claim 12 further comprising:
over-sampling the periodically measured leakage current values to reduce effects of white noise during measurements.

15. The method of claim 12 further comprising:
averaging groups of the periodically measured leakage current values into averaged periodically measured leakage current values.

16. The method of claim 12 further comprising:
digitally filtering the periodically measured leakage current values to remove unwanted frequencies that could interfere with collected data.

17. The method of claim 12 further comprising:
discharging the programmed voltage from the at least one part for a predetermined period of time; and
periodically measuring leakage current values of the at least one part while the programmed voltage is being discharged from the at least one part.

18. The method of claim 17 further comprising:
digitizing a curve from the periodically measured leakage current values measured while the programmed voltage is being discharged from the at least one part.

19. The method of claim 12 further comprising:
periodically measuring capacitance values and dissipation factor values of the at least one part while the at least one part is being charged and discharged.

20. A method for testing at least one multilayer ceramic capacitor part comprising:
charging, holding, and discharging at least one part with respect to a programmed voltage over a predetermined period of time;
periodically measuring at least one value corresponding to quality of each part to be tested while each part is being charged, held, and discharged, the at least one value selected from a group consisting of a voltage value, a current value, a leakage current value, a capacitance value, a dissipation factor value, and any combination thereof; and
digitizing curves from the periodically measured values collected while each part is being charged, held, and discharged.
